(19) United States
(12) Patent Application Publication
(10) Pub. No.: US 2010/0229077 A1
(43) Pub. Date: Sep. 9, 2010

(54) Information processing apparatus and error detection method

(75) Inventor: Norio Sugita, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/656,598

(22) Filed: Feb. 4, 2010

(30) Foreign Application Priority Data
Mar. 9, 2009 (JP) 2009-054454

(51) Int. Cl. H03M 13/09; G06F 11/10

(52) U.S. Cl. 714/807; 714/E11.032

(57) ABSTRACT

An information processing apparatus includes multiple bus slaves, a bus master that outputs address data having a base address value for specifying arbitrary bus slave among the multiple bus slaves, and an offset address value for specifying access position in the bus slave, a selection unit that outputs a selection signal for selecting the arbitrary bus slave to the multiple bus slaves according to the base address value output from the bus master, an error detecting code generation unit that outputs an error detecting code from the address data output from the bus master, and an error detection unit that detects an error in the address data according to the error detecting code, which is generated from the offset address value output from the bus master and the base address value for specifying the selected bus slave, and the error detecting code output from the error detecting code generation unit.

### INCORPORATION BY REFERENCE

This application is based upon and claims the benefit of priority from Japanese patent application No. 2009-054454, filed on Mar. 9, 2009, the disclosure of which is incorporated herein in its entirety by reference.

### BACKGROUND

1. Field of the Invention

The present invention relates to an information processing apparatus and an error detection method.

2. Description of Related Art

In recent years, microcomputers are often used to be mounted on a car. Further, a malfunction of the on-board microcomputer involve human lives, thus the importance of functional safety (idea of implementing functions so as to ensure the safety of systems and devices in case of a failure) is increasing and the microcomputers are implemented based on the idea of the functional safety.

Therefore, higher safety and reliability are required for the on-board microcomputers more than the microcomputers for other fields.

Japanese Unexamined Patent Application Publication No. 06-012269 discloses a technique that enables to detect an error by an error control apparatus including a CRC (Cyclic Redundancy Check) generator and an error detector. The error control apparatus is mounted between a standard bus not provided with the parity bit method and each adapter and memory connected to the standard bus, so as to append a CRC code to the end of the transfer data.

### SUMMARY

As explained in the related arts, the present inventor has found a problem that high safety and reliability are required for the on-board microcomputers.

An exemplary aspect of the present invention is an information processing apparatus that includes a plurality of bus slaves, a bus master that outputs address data, where the address data includes a base address value for specifying an arbitrary bus slave among the plurality of bus slaves, and an offset address value input to the specified bus slave for specifying an access position in the bus slave, a selection unit that outputs a selection signal for selecting the arbitrary bus slave to the plurality of bus slaves according to the base address value output from the bus master, an error detecting code generation unit that generates an error detecting code according to the address data output from the bus master and outputs the generated error detecting code, and an error detection unit that generates an error detecting code according to the address data, and detects an error in the address data according to the generated error detecting code and the error detecting code output from the error detecting code generation unit, where the address data is generated from the offset address value output from the bus master and the base address value for specifying the bus slave selected by the selection signal.

This enables to detect an error in the address data and thereby improving the safety and the reliability.

Another exemplary aspect of the present invention is an information processing apparatus that includes a first apparatus, a second apparatus connected to the first apparatus by a data bus, an error detecting code generation unit that, if the first apparatus outputs data to the second apparatus via the data bus, generates an error detecting code according to the data, and outputs the generated error detecting code to a bus for error detecting code which is different from the data bus, an error detection unit that generates an error detecting code according to the data output from the first apparatus to the data bus and input to the second bus, and detects an error in the data according to the generated error detecting code and the error detecting code output from the error detecting code generation unit to the bus for error detecting code.

This enables to detect an error in the data and thereby improving the safety and the reliability.

Another exemplary aspect of the present invention is a method of detecting an error that includes a bus master outputting address data, the address data including a base address value for specifying an arbitrary bus slave among a plurality of bus slaves, and an offset address value input to the specified bus slave for specifying an access position in the bus slave, selecting the arbitrary bus slave according to the base address value output from the bus master, generating a first error detecting code according to the address data output from the bus master, outputting the first error detecting code, generating the address data from the offset address value output from the bus master and the base address value for specifying the selected bus slave, generating a second error detecting code according to the generated address data, and detecting an error in the address data according to the first error detecting code and the second error detecting code.

This enables to detect an error in the address data and thereby improving the safety and the reliability.

An exemplary aspect of the present invention is a method of detecting an error that includes, if a first apparatus outputs data to a second data bus via a data bus, generating a first error detecting code according to the data, outputting the first error detecting code to a bus for error detecting code that is different from the data bus, generating a second error detecting code according to the data output from the first apparatus to the data bus and input to the second apparatus, and detecting an error in the data according to the first error detecting code and the second error detecting code.

This enables to detect an error in the data and thereby improving the safety and the reliability.

The present invention provides an information processing apparatus and an error detection method that enable to improve the safety and the reliability.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 illustrates a data bus configuration of an information processing apparatus according to an exemplary embodiment of the present invention;

FIG. 2 illustrates an address bus configuration of an information processing apparatus before applying the exemplary embodiment of the present invention; and

FIG. 3 illustrates an address bus configuration of an information processing apparatus according to the exemplary embodiment of the present invention.

### DETAILED DESCRIPTION OF THE EXEMPLARY EMBODIMENTS

### First Exemplary Embodiment

An example of applying the exemplary embodiment of the present invention to an APB (Advanced Peripheral Bus) buses is explained with reference to the drawings.

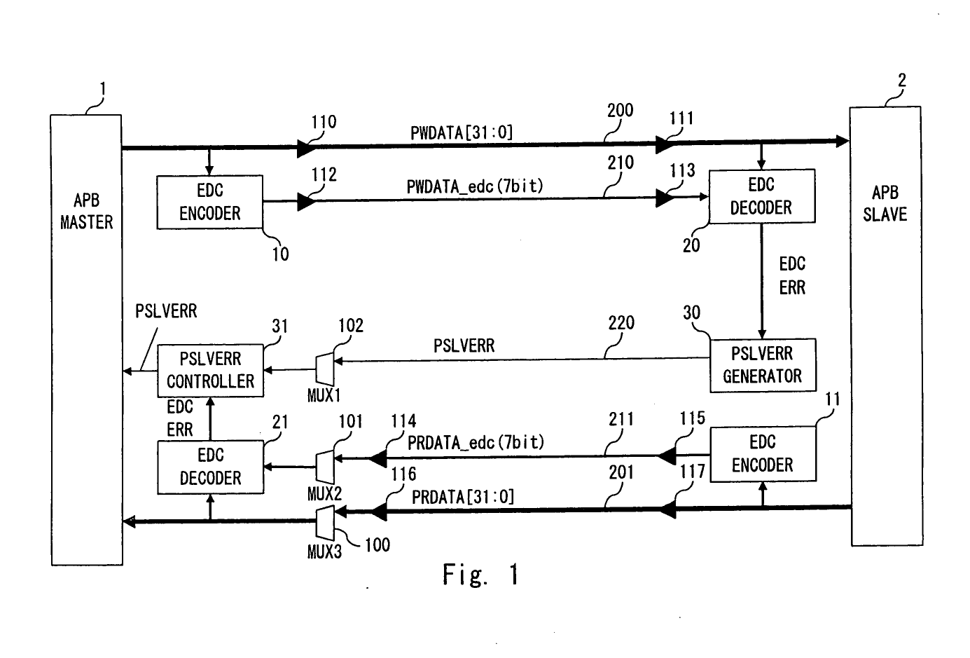

First, a data bus configuration of an information processing apparatus according to the exemplary embodiment of the present invention is described with reference to FIG. 1. FIG. 1 illustrates the data bus configuration of the information processing apparatus of the present invention.

The information processing apparatus according to this exemplary embodiment includes an APB master 1, an APB slave 2, EDC encoders 10 and 11, EDC decoders 20 and 21, a PSLVERR generator 30, and a PSLVERR controller 31.

The APB master 1 and the APB slave 2 are connected to each other by a data bus 200 and a data bus 201 which has a multiplexer 100 interposed therebetween. The EDC encoder 10 and the EDC decoder 20 are connected to each other by a bus for error detecting code 210. The EDC encoder 11 and the EDC decoder 21 are connected to each other by a bus for error detecting code 211 via a multiplexer 101. The PSLVERR generator 30 and the PSLVERR controller 31 are connected to each other by a PSLVERR signal line 220 via a multiplexer 102. Moreover, the data buses 200 and 201 and the buses for error detecting code 210 and 211 are provided with repeater buffers 110 to 117. Note that repeater buffers 110 to 117 are not limited to this exemplary embodiment, however various modifications can be made for the number and the position of buffer to dispose, for example. FIG. 1 illustrates an example in which the bus width of the data buses 200 and 201 is 32 bits, and the bus width of the buses for error detecting code 210 and 211 is 7 bits.

The APB master 1 is a device to be a bus master. The APB master 1 is a CPU (Central Processing Unit) or a DMA (Direct Memory Access) controller, for example.

The APB slave 2 is a device to be a bus slave. The APB slave 2 is a timer, an ADC (Analog Digital Converter) or the like, for example.

The EDC encoders 10 and 11 generate an error detecting code (EDC) according to the data output from the APB master 1. Further, the EDC encoders 10 and 11 output the generated error detecting code to the EDC decoders 20 and 21. The EDC encoders function as an error detecting code generation unit.

The EDC decoders 20 and 21 detect an error of data according to the data input to the APB slave 2, and the error detecting code output from the EDC encoders 10 and 11. Further, if the EDC decoder 20 detects an error, the EDC decoder 20 outputs EDCERR, which is a value indicating that the error in the data is detected, to the PSLVERR generator 30. The EDC decoder 21 further outputs EDCERR to the PSLVERR controller 31, if the error in the data is detected.

In response to EDCERR output from the EDC decoder 20, the PSLVERR generator 30 outputs PSLVERR, which is a value indicating of an error detection, to the PSLVERR controller 31.

In response to EDCERR output from the EDC decoder 21 and PSLVERR output from the PSLVERR generator 30, the PSLVERR controller 31 outputs PSLVERR to the APB master 1. The EDC decoder, the PSLVERR generator, and the PSLVERR controller function as an error detection unit.

Note that in an APB bus, there can be one APB master and multiple APB slaves.

However, in FIG. 1, only the APB slave 2, which is one of the APB slaves, is illustrated and other APB slaves are not illustrated. Further, the EDC decoders and the PSLVERR generators in the side of the APB slaves other than the APB slave 2 are also not illustrated. Accordingly, this exemplary embodiment illustrates the case in which the APB master 1 selects the APB slave 2 by an output to an address described later. Moreover, the data bus, the bus for error detecting code, and the PSLVERR signal line from the APB slaves other than the APB 2 are connected to the multiplexers 100, 101, and 102. The multiplexers 100, 101, and 102 select a signal from the signal line corresponding to the APB slave selected by the APB master 1 using the output to the address bus. Therefore, the data bus, the bus for error detecting code and the PSLVERR signal line, which are connected to the APB slaves other than the APB slave 2 are also not illustrated.

Next, the process in the data bus of the information processing apparatus according to the exemplary embodiment of the invention is explained hereinafter.

First, the APB master 1 outputs arbitrary 32 bits data (PWDATA [31:0]) to the APB slave 2 via the data bus 200.

The EDC encoder 10 obtains the data output from the APB master 1, and generates a 7 bits error detecting code (PWDATA_edc) according to the obtained data. Then, the EDC encoder 10 outputs the generated error detecting code to the EDC decoder 20 via the bus for error detecting code 210.

The EDC decoder 20 obtains the data, which is output from the APB master 1 and input to the APB slave 2, and also obtains the error detecting code output from the EDC encoder 10. Then, the EDC decoder 20 generates an error detecting code according to the obtained data, and evaluates whether there is an error in the data by comparing the generated error detecting code and the error detecting code output from the EDC encoder 10. The error in the data indicates, for example, that a bit inversion of the data is generated in the repeater buffers 110, 111, 116, and 117 that are provided for adjusting the delay time of a signal or shaping a waveform, due to an influence of external radiation.

The compared error detecting codes are in agreement and the evaluation indicates that there is no error in the data, the EDC decoder 20 will do nothing.

If the compared error detecting codes are not in agreement, and the evaluation indicates that there is an error in the data, the EDC decoder 20 outputs EDCERR to the PSLVERR generator 30. If the PSLVERR generator 30 receives the output of EDCERR from the EDC decoder 20, the PSLVERR generator 30 outputs PSLVERR to the PSLVERR controller 31.

On the other hand, the APB slave 2 obtains the data output from the APB master 1, and outputs the 32 bits data (PRDATA [31:0]) to the APB master 1 via the data bus 201 according to the obtained data.

The EDC encoder 11 obtains the data output from the APB slave 2, and generates 7 bits error detecting code (PRDATA_edc) according to the obtained data. Then, the EDC encoder 11 outputs the generated error detecting code to the EDC decoder 21 via the bus for error detecting code 211.

The EDC decoder 21 obtains the data, which is output from the APB slave 2 and input to the APB master 1, and also obtains the error detecting code output from the EDC encoder 11. Then, the EDC decoder 21 generates an error detecting code according to the obtained data, and evaluates whether there is an error in the data by comparing the generated error detecting code and the error detecting code output from the EDC encoder 11.

If the compared error detecting codes are in agreement, and the evaluation indicates that there is no error in the data, the EDC decoder 21 will do nothing.

If the compared error detecting codes are not in agreement, and the evaluation indicates that there is an error in the data, the EDC decoder 21 outputs EDCERR to the PSLVERR controller 31. If the PSLVERR controller 31 receives the output of EDCERR from the EDC decoder 20 or the output of PSLVERR from the PSLVERR generator 30, the PSLVERR controller 31 outputs PSLVERR to the APB master 1.

On the other hand, the APB master 1 waits for the data output from the APB slave 2 and the signal output from the PSLVERR controller 31.

If the APB master 1 receives the output of PSLVERR from the PSLVERR controller 31, that is, if there is an error in the data, the APB master 1 retransmits the data or performs processes corresponding to the error, such as stopping the process.

If the APB master 1 did not receive the output of PSLVERR from the PSLVERR controller 31, that is, if there is no error in the data, the APB master 1 continues the process using the obtained data.

Note that waiting in this case enables the APB master 1 to recognize that the error evaluation result is determined by providing a signal line indicating that the error evaluation result of the data is determined, separately from the signal line for outputting PSLVERR, even when the output of PSLVERR is not received, that is, when an error is not generated in the data.

Also note that an example is illustrated here about the case of applying to an APB data bus, however it is not limited to the APB data bus but can be applied to other buses.

As explained above, this exemplary embodiment enables to detect an error in data and thereby improving the safety and the reliability.

In this exemplary embodiment, since an error detecting code is output to a different bus from the data bus, the amount of data in the data bus and the amount of processes performed in the data bus do not increase. This suppresses from reducing the processing speed and improves the safety and the reliability.

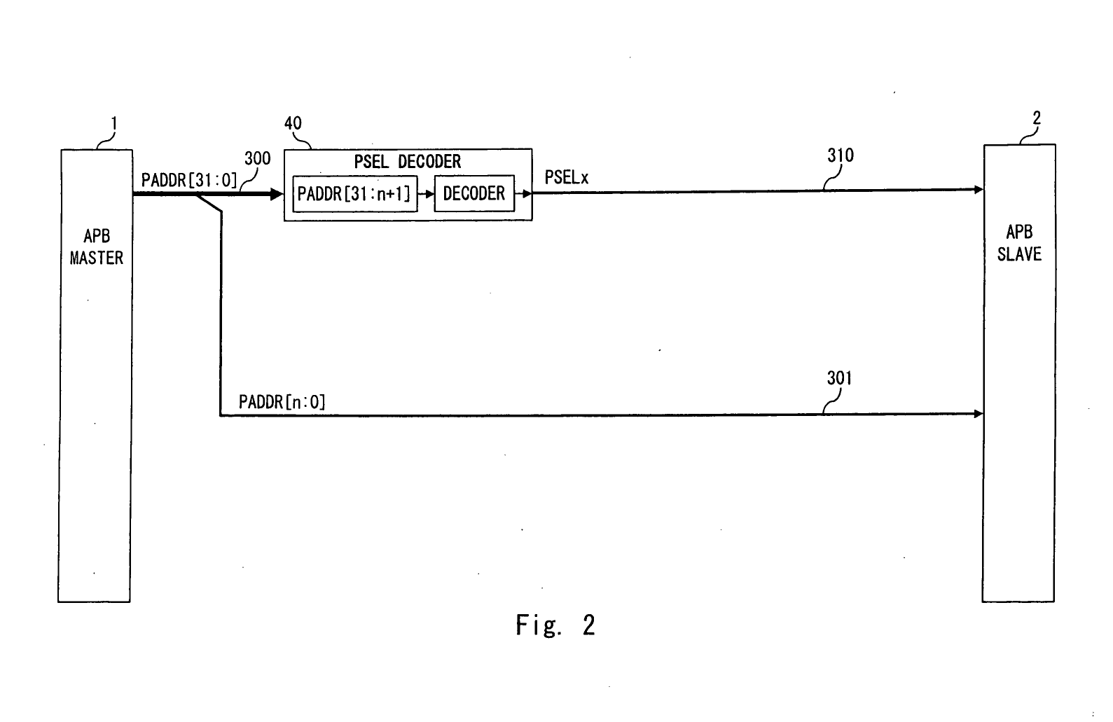

Next, in order to explain the address bus of the information processing apparatus according to the exemplary embodiment of the resent invention, firstly the address bus configuration of an information processing apparatus before applying the exemplary embodiment of the present invention is described with reference to FIG. 2. FIG. 2 illustrates the address bus configuration of the information processing apparatus before applying the exemplary embodiment of the present invention.

The information processing apparatus before applying the exemplary embodiment of the invention is provided with an APB master 1, an APB slave 2, and a PSEL decoder 40.

The APB master 1, the APB slave 2, and the PSEL decoder 40 are connected to each other by address buses 300 and 301. The PSEL decoder 40 and the APB slave 2 are connected to each other by a PSELx signal line 310. Note that FIG. 2 is an example in which the bus width of the address bus 300 is 32 bits and the bus width of the address bus 301 is n+1 bit. Also note that the address bus 301 transfers an offset address value (PADDR [n:0]) of n−0 bit (n+1 bit) among 32 bits address data (PADDR [31:0]) output to the address bus 300. The address bus 301 is the bus of n to 0 bit branched signal line among 32 bits signal line of the address bus 300, for example. Note that n is an integer from 0 to 30.

As the APB master 1 and the APB slave 2 are same as FIG. 1, the explanation is omitted.

The PSEL decoder 40 outputs a PSELx signal to the APB slave 2 according to a base address value (PADDR [31:n+1]) of 31 to n+1 bit (32-(n+1) bit) among the address data input from the APB master 1.

Note that as with FIG. 1, the APB slaves other than the APB slave 2 are not illustrated. Accordingly, the PSELx signal line and the address bus which are connected from the PSEL decoder 40 to the APB slaves other than the APB slave 2 are also not illustrated. Further, the repeater buffers are also not illustrated.

Next, the process of the address bus of the information processing apparatus before applying the exemplary embodiment of the invention is explained hereinafter.

First, the APB master 1 outputs arbitrary address data to the address bus 300. Then, the offset address value among the address data output from the APB master 1 is input to the APB slave 2 via the address bus 301.

The PSEL decoder 40 obtains the address data output from the APB master 1, and compares the base address value among the obtained address data with the base address values of all the APB slaves. The base address value of the APB slave is 31 to n+1 bit (32-(n+1) bit) address value in the 32 bits top address value in the address assigned to the APB slave. Then, the active PSELx signal is output to the APB slave having the matched base address. Accordingly, if the base address value of the APB slave 2 and the base address value among the address data output from the APB master 1 are in agreement, the PSEL decoder 40 outputs the active PSELx signal to the APB slave 2 via the PSELx signal line 310. The PSEL decoder 40 can compare as described above by having the base address values of all the APB slaves, for example.

As described above, in the APB address bus, the APB master selects the APB slave according to the base address value in the address data, and specifies an accessing address in an address area assigned to the APB slave, which is selected by the offset address value. That is, 32 bits address data is not input to the APB slave as it is. Note that the size of the address area is the size of the n-th power of 2.

Accordingly, the PSELx signal and the offset address value are input to the APB slave 2 side, and the address data output by the APB master 1 is unknown. Thus the error detection method of data applied to the abovementioned data bus cannot be applied in this state.

Therefore, in this exemplary embodiment, an error in the data of the address bus is detected by a means described later. Also note that an example is illustrated here about the case of applying to an APB data bus, however it is not limited to the APB data bus but can be applied to other buses. For example, this exemplary embodiment can be applied to an address bus configuration that adopts the memory mapped I/O method and a part of the values of the address data is input to the bus slave so as to reduce wiring, as described above.

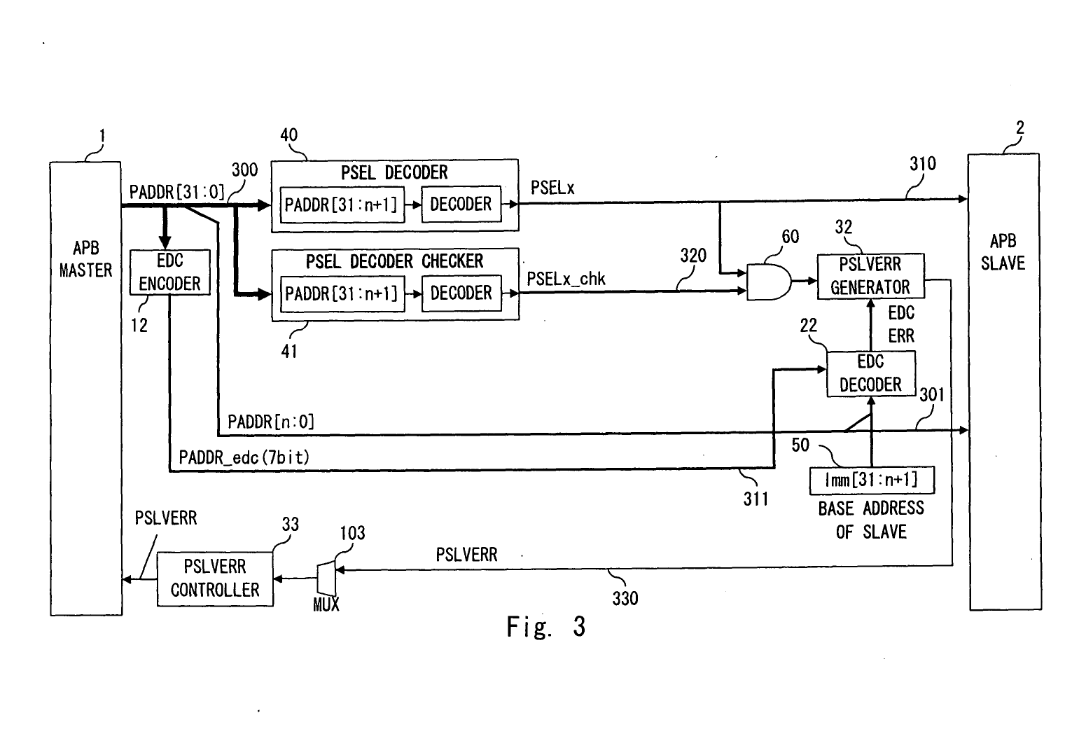

Next, the data bus configuration of the information processing apparatus according to the exemplary embodiment of the present invention is described with reference to FIG. 3. FIG. 3 illustrates the address bus configuration of the information processing apparatus according to the exemplary embodiment of the present invention. As FIG. 3 is the information processing apparatus applying the exemplary embodiment of the present invention to FIG. 2, similar connection relationship and the components as FIG. 2 are not explained.

The information processing apparatus according to this exemplary embodiment is provided with an APB master 1, an APB slave 2, an EDC encoder 12, an EDC decoder 22, a PSLVERR generator 32, a PSLVERR controller 33, a PSEL decoder 40, a PSEL decoder checker 41, a base address storage apparatus 50, and an AND circuit 60.

The APB master 1, the APB slave 2, the EDC encoder 12, the PSEL decoder 40, and the PSEL decoder checker 41 are connected to each other by address buses 300 and 301. The AND circuit 60 is connected to the APB slave 2 and the PSEL decoder 40 by a PSELx signal line 310, and connected to the PSEL decoder checker 41 by a PSELx_chk signal line 320. The EDC encoder 12 and the EDC decoder 22 are connected to each other by a bus for error detecting code 311. The PSLVERR controller 33 and the PSLVERR generator 32 are connected to each other by the PSLVERR signal line 330 via a multiplexer 103. Note that FIG. 3 illustrates the example in which the bus width of the bus for error detecting code 311 is 7 bits.

The EDC encoder 12 generates an error detecting code (EDC) according to the address data output from the APB master 1. Further, the EDC encoder 12 outputs the generated error detecting code to the EDC decoder 22. The EDC encoder functions as an error detecting code generation unit.

The EDC decoder 22 detects an error of the address data according to an offset address value input to the APB slave 2, a base address value stored to the base address storage apparatus 50, and an error detecting code output from the EDC encoder 12. If an error is detected, the EDC decoder 22 outputs EDCERR, which is a value indicating that an error of the address data is detected, to the PSLVERR generator 32.

In response to EDCERR output from the EDC decoder 22, the PSLVERR generator 32 outputs PSLVERR, which is a value indicating that an error is detected, to the PSLVERR controller 33. Further, the PSLVERR generator 32 detects an error of the PSELx signal output by the PSEL decoder 40 according to an AND value output from the AND circuit 60, and outputs PSLVERR to the PSLVERR controller 33 accordingly.

The PSLVERR controller 33 outputs PSLVERR to the APB master 1 according to PSLVERR output from the PSLVERR generator 32. The EDC decoder, the PSLVERR generator, and the PSLVERR controller function as an error detection unit.

The PSEL decoder 40 outputs a PSELx signal to the APB slave 2 according to the base address value among the address data input from the APB master 1. The PSEL decoder 40 further outputs a PSELx signal to the AND circuit 60.

The PSEL decoder checker 41 outputs a PSELx_chk signal to the AND circuit 60 according to the base address value among the address data input from the APB master 1.

The base address storage apparatus 50 stores the base address value of the APB slave 2. The base address storage apparatus 50 includes an arbitrary storage means such as a register or a memory. The base address storage apparatus corresponds to the base address storage unit.

The AND circuit 60 outputs an AND value of the PSELx signal output from the PSEL decoder 40 and the PSELx_chk signal output from the PSEL decoder checker 41, to the PSLVERR generator 32.

Note that as with FIG. 2, the APB slaves other than the APB slave 2 are not illustrated. Therefore, the data bus, the bus for error detecting code and the PSLVERR signal line which are connected to the APB slaves other than the APB slave 2 are also not illustrated. Accordingly, this exemplary embodiment illustrates the case in which the APB master 1 selects the APB slave 2 by an output to the address bus. Further, the EDC decoder, PSLVERR generator, the base address storage apparatus, and the AND circuit of the APB slaves other than the APB slave 2 are also not illustrated.

Next, the process in the address bus of the information processing apparatus according to the exemplary embodiment of the invention is explained hereinafter.

First, the APB master 1 outputs arbitrary address data to the address bus 300. Then, the offset address value is input to the APB slave 2 via the address bus 301 among the address data output from the APB master 1.

The PSEL decoder 40 and the PSEL decoder checker 41 obtain the address data output from the APB master 1, and compare the base address value in the obtained address data with the base address values of all the APB slaves.

Then, the PSEL decoder 40 activates and outputs a PSELx signal to the APB slave with a matched base address and the AND circuit that corresponds to the APB slave. That is, among the base address value of the APB slave 2 and the address data output from the APB master 1, if the base address value is in agreement, the PSEL decoder 40 outputs the activated PSELx signal to the APB slave 2 and the AND circuit 60.

Further, the PSEL decoder checker 41 activates the PSELx_chk signal, and outputs it to the AND circuit that corresponds to the APB slave with the matched base address value. That is, among the base address value of the APB slave 2 and the address data output from the APB master 1, if the base address value is in agreement, the PSEL decoder 40 outputs the activated PSELx_chk signal to the AND circuit 60. The PSEL decoder 40 and the PSEL decoder checker 41 can compare as described above by having base address values of all the APB slaves, for example.

If the AND circuit 60 obtains the PSELx signal output from the PSEL decoder 40 and the PSELx_chk signal output from the PSEL decoder checker 41, the AND circuit 60 outputs an AND value of the obtained PSELx signal and PSELx_chk signal to the PSLVERR generator 32.

On the other hand, the EDC encoder 12 obtains the address data output from the APB master 1 via the address bus 300, and generates 7 bits error detecting code (PWDATA_edc) according to the obtained address data. Then, the EDC encoder 10 outputs the generated error detecting code to the EDC decoder 22 via the bus for error detecting code 311.

The EDC decoder 22 obtains the offset the address data, which is generated from address value, which is output from the APB master 1 and input to the APB slave 2, and the base address value of the APB slave 2 and output from the base address storage apparatus 50. The EDC decoder 22 further obtains the error detecting code output from the EDC encoder 12. Then, the EDC decoder 22 generates an error detecting code according to the obtained data, and evaluates whether there is an error in the data by comparing the generated error detecting code and the error detecting code output from the EDC encoder 12.

The address data obtained by the EDC decoder 22 is to be generated using a signal line of 32-(n+1) bit which outputs the base address value from the base address storage apparatus 50, and the signal line of n+1 bit of address bus 301 to which the offset address value is transferred. Then the address data is input to the EDC decoder 22. Further, the EDC decoder 22 may separately obtain the base address value and the offset address value, and generate the address data according to the obtained base address value and the offset address value.

If the compared error detecting codes are in agreement, and the evaluation indicates that there is no error in the data, the EDC decoder 22 will do nothing.

If the compared error detecting codes are not in agreement, and the evaluation indicates that there is an error in the data, the EDC decoder 22 outputs EDCERR to the PSLVERR generator 32.

If the PSLVERR generator 32 receives the output of EDCERR from the EDC decoder 22, or if the PSLVERR generator 32 receives the value indicating that the PSELx signal and the PSELx_chk signal are not in agreement from the AND circuit 60, the PSLVERR generator 32 outputs PSLVERR to the PSLVERR controller 33. Then, if the PSLVERR controller 33 receives the output of EDCERR from the EDC decoder 22, the PSLVERR outputs PSLVERR to the APB master 1.

That is, the PSLVERR generator 32 detects a disagreement if active values of the PSELx signal and the PSELx_chk signal is “1”, and if an AND value of these signal is not “1”. Further, at this time, in order not to evaluate that there is an error when both of the PSELx signal and the PSELx_chk signal are inactive, which is “0”, the PSELx signal is input to the PSLVERR generator 32, so that the evaluation indicates that an error is detected only when the PSELx signal is active, which is “1”. This is how an error of the PSELx signal is detected. Note that in order not to evaluate that there is an error when both of the PSELx signal and the PSELx_chk signal are inactive, a disagreement of the signals can be detected by an XOR circuit or an XNOR circuit instead of the AND circuit.

Also note that the operation when PSLVERR of APB master 1 is received or not received is same as the abovementioned process for the data bus.

Thus, in this exemplary embodiment, even if only the offset address value is input to the APB slave side, by storing the base address value to the APB slave side in advance, it is possible to generate the address data according to the offset address value input to the APB slave side and detect an error by the error detecting code generated according to the address data.

That is, it is possible to detect an error generated in the offset address value from when the offset address value is output from the APB master 1 until being input to the APB slave 2.

Moreover, in this exemplary embodiment, address data is generated according to the base address value stored to the APB slave side in advance, corresponding to the APB slave 2 selected by the PSELx signal, and an error can be detected by the error detecting code generated according to the address data. Accordingly, if an error is generated in the base address value input to the PSEL decoder 40, and the base address value input to the PSEL decoder 40 is different from the base address value input to the EDC encoder 12, the error detecting codes generated by the EDC encoder 12 and the EDC decoder 22 are not in agreement. Then an error can be detected.

That is, it is possible to detect an error generated in the base address value among the address data from when the base address value is output from the APB master 1 until being input to the PSEL decoder 40.

The present invention is not limited to the above exemplary embodiment, but can be modified as appropriate within the scope of the present invention. For example, as for the PSLVERR controller 33, same PSLVERR controller may be provided to the data bus and the address bus.

Furthermore, in this exemplary embodiment, the EDC encoder 12 outputs an error detecting code to the EDC decoder 22 by the bus for error detecting code 311, which is different from the address bus 301. However the error detecting code may be output with the offset address value via the address bus 301.

Moreover in this exemplary embodiment, the EDC decoder and the PSLVERR generator are provided to correspond to each of the bus slaves, however it is not limited to this. For example, a common EDC decoder and PSLVERR generator among the bus slave side may be provided. Then, the offset address value corresponding to the bus slave according to the PSELx signal and the base address value stored by the base address storage apparatus may be input to the EDC decoder.

As explained above, this exemplary embodiment enables to detect an error in the address data and improve the safety and the reliability. That is, in this exemplary embodiment, even if all the bits of the address data are not received by the bus slave side, the bus slave side stores the base address value and restores the address data based on the base address value, so that an error can be detected as with the data bus.

Further, this exemplary embodiment enables to detect an error in the PSELx signal that selects the bus slave accessed by the bus master, thereby improving the safety and the reliability. Furthermore, in this exemplary embodiment, an error detecting code is output to the bus different from the address bus, thus the amount of data and the amount of processes in the address bus will not increase. This suppresses from reducing the processing speed and improves the safety and the reliability.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described. above.

Furthermore, it is noted that, Applicant's intent is to encompass equivalents of all claim elements, even if amended later during prosecution.

What is claimed is:

1. An information processing apparatus comprising:
a plurality of bus slaves;
a bus master that outputs address data, the address data including a base address value for specifying an arbitrary bus slave among the plurality of bus slaves, and an offset address value input to the specified bus slave for specifying an access position in the bus slave;
a selection unit that outputs a selection signal for selecting the arbitrary bus slave to the plurality of bus slaves according to the base address value output from the bus master;
an error detecting code generation unit that generates an error detecting code according to the address data Output from the bus master and outputs the generated error detecting code; and
an error detection unit that generates an error detecting code according to the address data, the address data being generated from the offset address value output from the bus master and the base address value for specifying the bus slave selected by the selection signal, and detects an error in the address data output from the bus master according to the generated error detecting code and the error detecting code output from the error detecting code generation unit.

2. The information processing apparatus according to claim 1, wherein the information processing apparatus further comprises a selection unit for inspection that outputs an active value to a selection signal for inspection that corresponds to the bus slave selected according to the base address value output from the bus master among the selection signals for inspection corresponding to the plurality of bus slaves;
wherein the selection unit outputs an active value to the selection signal corresponding to the selected bus slave among the selection signal, and
the error detection unit detects an error of the selection signal by comparing values of the selection signal and the selection signal for inspection.

3. The information processing apparatus according to claim 1, wherein the offset address value is output from the bus master to the bus slave via an address bus, and the error detecting code is output from the error detecting code generation unit to the error detection unit via a bus for error detecting code that is different from the address bus.

4. The information processing apparatus according to claim 1, wherein the error detection unit outputs an error detection value indicating of an error detection if an error is detected.

5. An information processing apparatus comprising:
a first apparatus;
a second apparatus connected to the first apparatus by a data bus;
an error detecting code generation unit that, if the first apparatus outputs data to the second apparatus via the data bus, generates an error detecting code according to the data, and outputs the generated error detecting code to a bus for error detecting code which is different from the data bus; and
an error detection unit that generates an error detecting code according to the data output from the first apparatus to the data bus and input to the second bus, and detects an error in the data according to the generated error detecting code and the error detecting code output from the error detecting code generation unit to the bus for error detecting code.

6. The information processing apparatus according to claim 5, wherein either one of the first apparatus and the second apparatus is a bus master, and another one of the first apparatus and the second apparatus is a bus slave.

7. The information processing apparatus according to claim 5, wherein the error detection unit outputs an error detection value indicating of an error detection if an error is detected.

8. A method of detecting an error comprising:
a bus master outputting address data, the address data including a base address value for specifying an arbitrary bus slave among a plurality of bus slaves, and an offset address value input to the specified bus slave for specifying an access position in the bus slave;
selecting the arbitrary bus slave according to the base address value output from the bus master;
generating a first error detecting code according to the address data output from the bus master;
outputting the first error detecting code;
generating the address data from the offset address value output from the bus master and the base address value for specifying the selected bus slave;
generating a second error detecting code according to the generated address data; and
detecting an error in the address data output from the bus master according to the first error detecting code and the second error detecting code.

9. A method of detecting an error comprising:
if a first apparatus outputs data to a second data bus via a data bus, generating a first error detecting code according to the data;
outputting the first error detecting code to a bus for error detecting code that is different from the data bus;
generating a second error detecting code according to the data output from the first apparatus to the data bus and input to the second apparatus; and
detecting an error in the data according to the first error detecting code and the second error detecting code.
